(19) United States
(12) Patent Application Publication
(10) Pub. No.: US 2013/0062628 A1
(43) Pub. Date: Mar. 14, 2013

(54) METHODS FOR THE EPITAXIAL GROWTH OF SILICON CARBIDE

(71) Applicants: Hrishikesh DAS, Starkville, MS (US); Swapna SUNKARI, Starkville, MS (US); Timothy OLDHAM, Starkville, MS (US); Janna B. CASADY, Starkville, MS (US)

(72) Inventors: Hrishikesh DAS, Starkville, MS (US); Swapna SUNKARI, Starkville, MS (US); Timothy OLDHAM, Starkville, MS (US); Janna B. CASADY, Starkville, MS (US)

(73) Assignee: SEMISOUTH LABORATORIES, INC., Starkville, MS (US)

(21) Appl. No.: 13/590,787

(22) Filed: Aug. 21, 2012

Related U.S. Application Data
(60) Provisional application No. 61/533,205, filed on Sep. 10, 2011.

(51) Int. Cl. C30B 25/10; H01L 29/24

(52) U.S. Cl. 257/77; 117/97; 117/95; 257/E29.104

(57) ABSTRACT

A method for the epitaxial growth of SiC is described which includes contacting a surface of a substrate with hydrogen and HCl, subsequently increasing the temperature of the substrate to at least 1550° C. and epitaxially growing SiC on the surface of the substrate. A method for the epitaxial growth of SiC is also described which includes heating a substrate to a temperature of at least 1550° C., contacting a surface of the substrate with a C containing gas and a Si containing gas at a C/Si ratio of 0.5-0.8 to form a SiC buffer layer and subsequently contacting the surface with a C containing gas and a Si containing gas at a C/Si ratio >0.8 to form a SiC epitaxial layer on the SiC buffer layer. The method results in silicon carbide epitaxial layers with improved surface morphology.

This application claims the benefit of Provisional U.S. Patent Application Ser. No. 61/533,205, filed on Sep. 10, 2011, which is incorporated by reference herein in its entirety.

### BACKGROUND

1. Technical Field

This application relates generally to epitaxial growth processes and, in particular, to methods for the epitaxial growth of SiC and to products produced thereby.

2. Background of the Technology

Homoepitaxial growth on 4H Silicon Carbide (SiC) is an important technology in fabricating low-loss power devices. A remarkable success in the development of the SiC power devices has been observed in recent years due to the significant advances in the growth of epitaxial layers on good quality substrates. Epitaxial layers grown on 4° off-axis substrates are prone to step-bunching and triangular defects [1]. Step-bunching and surface roughness not only increases the leakage current on Schottky barrier diodes, but also decreases the breakdown voltage. High quality epitaxial layers free of defects with smooth surface morphology are needed to improve device performance [2, 3].

Aigo et al. [4] have demonstrated a surface roughness Ra of 0.2 nm on a 10 μm thick epilayer grown on 4° off-axis substrates. Epitaxial growth on 3″ substrates with uniformities of 3% and 6% for thickness and doping respectively and having a surface roughness (RMS) of 1.2 nm have been reported [5].

There still exists a need, however, for epitaxially grown layers having improved surface roughness and better thickness and doping uniformities.

### SUMMARY

A method is provided which comprises:

heating a semiconductor substrate to a first temperature of 1300-1500° C.;

contacting a surface of the substrate with hydrogen and HCl;

subsequently increasing the temperature of the substrate to a second temperature of at least 1550° C.;

epitaxially growing SiC on the surface of the substrate to form a SiC epitaxial layer on the substrate.

A method is also provided which comprises:

heating a semiconductor substrate to a first temperature of 1300-1500° C.;

contacting a surface of the substrate with hydrogen and HCl;

subsequently heating the substrate to a second temperature of at least 1550° C.;

contacting a surface of the substrate with a C containing gas and a Si containing gas at a C/Si ratio of 0.5-0.8 to form a SiC buffer layer on the surface of the substrate; and;

subsequently contacting the surface of the SiC buffer layer with a C containing gas and a Si containing gas at a C/Si ratio >0.8 to form a SiC epitaxial layer on the SiC buffer layer.

A method is also provided which comprises:

heating a semiconductor substrate to a temperature of at least 1550° C.;

contacting a surface of the substrate with a C containing gas and a Si containing gas at a C/Si ratio of 0.5-0.8 to form a SiC buffer layer on the surface of the substrate; and;

subsequently contacting the surface of the SiC buffer layer with a C containing gas and a Si containing gas at a C/Si ratio >0.8 to form a SiC epitaxial layer on the SiC buffer layer.

The SiC epitaxial layer can be formed at a higher growth rate than the SiC buffer layer. The SiC buffer layer can be formed at a growth rate of 1 μm/hr to 8 μm/hr and the SiC epitaxial layer can be formed at a growth rate >10 μm/hr or >20 μm/hr.

According to some embodiments, the SiC epitaxial layer can be formed or epitaxially grown at a pressure of 80 mbar to 120 mbar, 90 mbar to 110 mbar or 95 mbar to 105 mbar.

### BRIEF DESCRIPTION OF THE DRAWINGS

FIG. 1(a) is a 10×10 μm² AFM surface roughness scan of an unoptimized SiC epitaxial layer grown on a substrate, wherein the SiC layer has a thickness of 6 μm and an RMS roughness of 1.39 nm.

FIG. 1(b)b is a 10×10 μm² AFM surface roughness scan of a SiC epitaxial layer grown on a substrate wherein the substrate was pre-etched with H₂/HCl prior to epitaxial growth and wherein the SiC layer has a thickness of 6 μm and an RMS roughness of 0.55 nm.

FIG. 1(c) is a 10×10 μm² AFM surface roughness scan of a SiC epitaxial layer grown on a substrate wherein the substrate was pre-etched with H₂/HCl prior to epitaxial growth and optimized buffer having and wherein the SiC layer has a thickness of 6 μm and an RMS roughness of 0.32 nm.

FIG. 1(d) is a 10×10 μm² AFM surface roughness scan of a SiC epitaxial layer grown on a substrate wherein the SiC epitaxial layer is grown with an optimized 30 μm/hr growth epi process and wherein the SiC epitaxial layer has a thickness of 15 μm and an RMS roughness of 0.34 nm.

FIG. 1(e) is a 10×10 μm² AFM surface roughness scan of a SiC epitaxial layer grown on a substrate wherein the SiC epitaxial layer is grown with an optimized 30 μm/hr growth epi process and wherein the SiC epitaxial layer has a thickness of 53 μm and an RMS roughness 0.39 nm.

FIG. 1(f) is a 10×10 μm² AFM surface roughness scan of a typical substrate having an RMS roughness of 0.9 nm-1.1 nm.

FIG. 2 is a 10×10 μm² AFM surface roughness scan of a SiC epitaxial layer grown on a substrate wherein the SiC epitaxial layer is grown with an optimized 30 μm/hr growth epi process at a pressure of 100 mbar and wherein the SiC epitaxial layer has a thickness of 15 μm and an RMS roughness of 0.23 nm.

FIG. 3A shows the intra-wafer normalized profiles of thickness uniformity for SiC epitaxial layers grown under a Cl/Si ratio had of 3.0.

FIG. 3B shows the intra-wafer normalized profiles of doping uniformity for SiC epitaxial layers grown under a Cl/Si ratio had of 3.0.

FIG. 4A is a schematic showing wafer-to-wafer thickness (0.9%) for a run of six 4″ wafers.

FIG. 4B is a schematic showing doping (2%) homogeneity for a run of six 4″ wafers.

FIG. 5A is a graph showing the Raman spectra of 15 μm thick epitaxial layers grown with a 30 μm/hr growth process.

FIG. 5B is a graph showing the Raman spectra of 15 μm thick epitaxial layers grown with an 8 μm/hr growth process.

FIG. 6 is an x-ray diffraction (XRD) pattern for a 15 μm epitaxial layer grown with the 30 μm/hr process wherein the inset shows the rocking curves of epitaxial layers grown with the 8 μm/hr and 30 μm/hr growth processes having FWHM widths of 23.0 and 26.6 arcsecs respectively.

FIG. 7 is a graph showing the XRD rocking curves of two epitaxial layers grown with and without the optimizations wherein the un-optimized epitaxial layer has a wider peak having a FWHM of 37.1 arcsec and wherein the optimized epitaxial layer is of better quality exhibiting a narrower peak having a FWHM of 23.0 arcsec.

### DETAILED DESCRIPTION

A method for the epitaxial growth of silicon carbide is described. The method results in silicon carbide epitaxial layers with improved surface morphology. The method also results in a reduction or elimination of step-bunching and a reduction in surface roughness. According to some embodiments, a surface roughness of 0.3 nm can be achieved on substrates having a 1 nm surface roughness.

Various approaches have been taken to achieve smoother epitaxial surfaces. These approaches include the following.

1) Growth Temperature: Lower temperatures (1500° C.-1550° C.) are usually found to be favorable for smoother epi.

2) C/Si ratio: Lower C/Si ratio is found beneficial in reducing step-bunching.

3) Pre-Etching: In 4° off axis substrates, H₂ etching before growth has been found to reduce roughness.

Each of these approaches has various shortcomings. For example, growing at lower temperatures is a tradeoff between surface roughness and other factors like growth rate and formation of triangular defects. The methods described herein are sufficiently robust to grow SiC at higher temperatures (e.g., 1650° C.-1700° C.). Even at these higher temperatures, surface roughness is kept very low. This enables higher growth rates and suppresses the formation of triangular defects which can be a problem for growth at lower temperatures.

The method described herein can be used to eliminate the commonly observed problem of step bunching in epitaxial growth on off-cut silicon carbide substrates. This method can also promote the growth of smoother epitaxial layers by adding an optimized graded buffer before growth.

Better surface morphology of epitaxial layers is important for device performance. Smoother epitaxial layers result in lower leakage in diodes. In MOSFETS, smoother epitaxial layers result in lower scattering and improved channel mobility. A smoother surface also correlates with fewer defects in the material.

Semiconductor device fabricated on epitaxial layers made using the process described herein benefit from the improved surface morphology of the epitaxial layers. The inherent quality of smoother epitaxial layers results in improvements in almost all aspects of device performance. For diodes, a smoother surface results in better ideality, barrier formation and lesser leakage. For MOSFETS, better channel mobility can be achieved due to lesser surface states and scattering. In general smoother surfaces result in better passivation and lesser surface leakage paths.

According to some embodiments, a method is provided wherein the substrate is pre-etched with hydrogen and hydrochloric acid prior to epitaxial growth. According to some embodiments, this pre-etch of the substrate by hydrogen and hydrochloric acid occurs during the heat up ramp and before starting epitaxial growth. Etching with hydrogen and hydrochloric acid prior to epitaxial growth can reduce or eliminate step bunching in the epitaxial layers thereby making the layers smoother.

According to some embodiments, a buffer is grown before the actual epitaxial growth. The start of the buffer is grown at a low growth rate (between 1 μm/hr and 8 μm/hr) and with a very low Carbon to Silicon ratio (C/Si). This buffer is then ramped up to the target epitaxial layer flows with continuously varying growth rate and C/Si ratio. This results in a smoother morphology for the target epitaxial layer. According to some embodiments, the buffer is grown after etching with hydrogen and hydrochloric acid to further reduce surface roughness.

According to some embodiments, the method involves etching the substrate prior to epitaxial growth. An exemplary pre-etch process is set forth below.

a. Substrate is heated to 1400° C. with hydrogen flowing in the chamber

b. HCl is introduced in the chamber at 1400° C.

c. Substrate is held at 1400° C. for pre-defined period of time

d. Temperature is ramped to epitaxial growth temperature of 1550° C.-1650° C.

e. Substrate is held at process temperature for pre-defined period of time.

According to some embodiments, a SiC buffer layer is grown on the substrate at a relatively low growth rate and with a relatively low C/Si ratio of 0.5-0.8. Growth under these conditions is continued for a certain period of time. The growth conditions are then ramped up to the process growth rate and C/Si ratio. This ramp is done over a pre-defined period of time. After the ramp up, the actual epitaxial growth is started.

### Experimental

The practice of this invention can be further understood by reference to the following examples, which are provided by way of illustration only are not intended to be limiting.

The epitaxial growth of 4H—SiC on 100 mm 4° off-axis substrates grown in a multi-wafer CVD planetary reactor. Highly uniform epitaxial layers with thickness and doping uniformities of 1.75% and 1.46% respectively were grown in a 6×4″ planetary reactor. Surface roughness (RMS) was improved from 1.39 nm to 0.32 nm by a combination of H₂/HCl pre-etch and an optimized buffer. The optimizations were transferred to a 25-30 μm/hr growth rate process that maintained similar surface roughness even for a 53 μm thick epitaxial layer. The epitaxial layer quality was verified by Raman spectroscopy and XRD measurements.

The epitaxial growth was conducted in an Aixtron VP2400, a commercial multi-wafer hot-wall CVD planetary reactor. Commercially available 4 inch, n-type, 4° off-axis, Si-face 4H—SiC substrates were used for this work. The epitaxial growth was conducted with a H₂—SiH₄—C₃H₈—HCl chemistry. The growth pressure was varied from 100 mbar to 200 mbar, while the growth temperature was varied between 1600-1650° C. The C/Si ratio, Cl/Si ratio and H₂ flows were varied to establish the optimal conditions for epitaxial growth.

Fourier Transform Infrared spectroscopy (FTIR), mercury probe Capacitance-Voltage (CV), Atomic Force Microscopy (AFM), X-Ray Diffraction (XRD) and Raman spectroscopy were used to characterize the epitaxial layers. Epitaxial layer thickness was measured using a MKS Filmexpert 2140 on a 17 point grid with 3 mm edge exclusion on each wafer. The doping concentration was measured by an automated SSM model 495i Hg probe CV tool by mapping 13 points across the wafer, with an edge exclusion of 3 mm. AFM measurements were done on a Dimension Icon AFM system with ScanAsyst. XRD was acquired with a PANalytical X'Pert MRD 6-axis diffractometer equipped with a Copper X-ray tube and sealed proportional detector. Raman spectra were obtained by a LabRam J-Y Spectrometer with a HeNe laser (632.8 nm wavelength) and an 1800 gr/mm grating.

### Results and Discussion

Surface Roughness

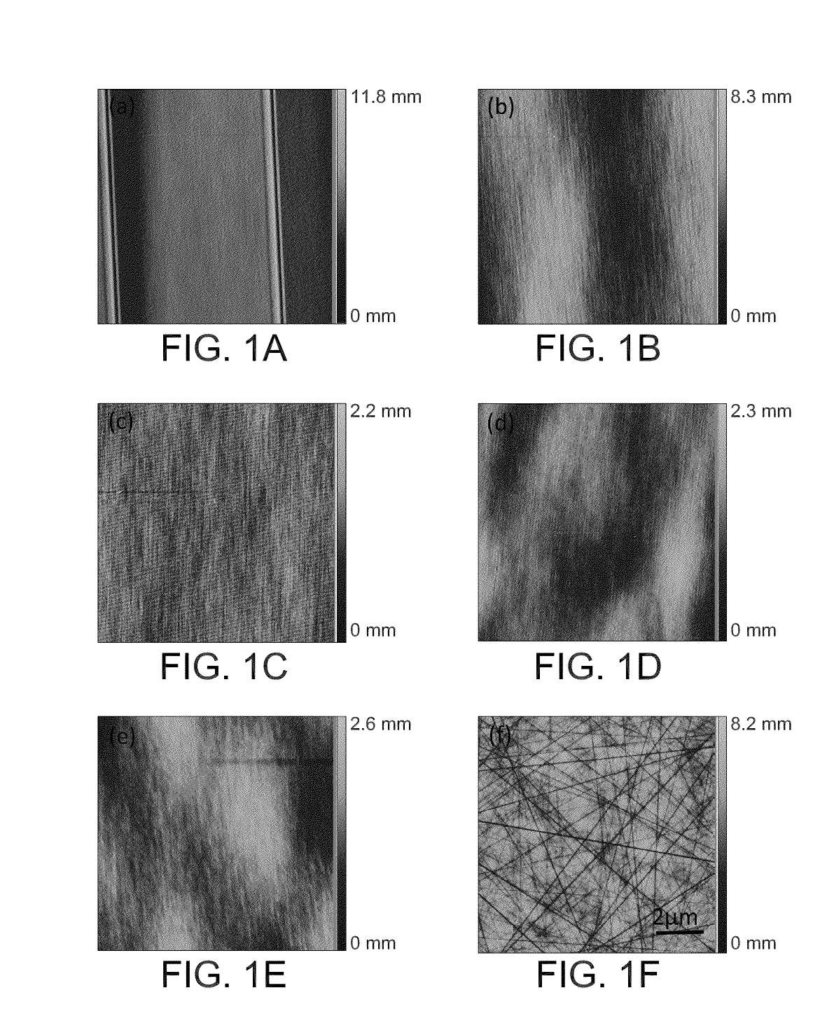

Surface roughness of the epitaxial layers was monitored with AFM scans on 10×10 μm² areas at five locations on each wafer. Process optimization for a smoother surface was done by growing epitaxial layers of 6 μm thickness under different conditions keeping a growth rate of 8 μm/hr. FIG. 1a shows an epitaxial layer before any optimizations, having sporadic step bunching and a RMS roughness value of 1.39 nm.

An optimized etch with H₂ and HCl during heat up and pre-growth was then added to the growth process. The grown epitaxial layer was found to be free from any step-bunching and had a RMS roughness of 0.55 nm as shown in FIG. 1b. Adding too much HCl to the pre-growth etch process may result in a rougher surface with visible pitting. The H₂/HCl flows and the etch time can be varied to achieve the desired surface characteristics. To further reduce the surface roughness, an optimized buffer layer was added after the pre-etch process. The buffer layer was grown with a much lower growth rate. This further reduced the surface roughness to 0.32 nm as shown in FIG. 1c. This optimized growth process was transferred to a 30 μm/hr growth regime.

FIG. 1d shows a 15 μm epitaxial layer grown at 30 μm/hr. The surface roughness (RMS) increased only marginally to 0.34 nm. A 53 μm thick epitaxial layer was grown to check the degradation in surface morphology with increase in thickness. FIG. 1e shows the AFM scan of this epilayer with a surface roughness of 0.39 nm. All the substrates used had surface roughness between 0.9 nm-1.1 nm as seen in FIG. 1f.

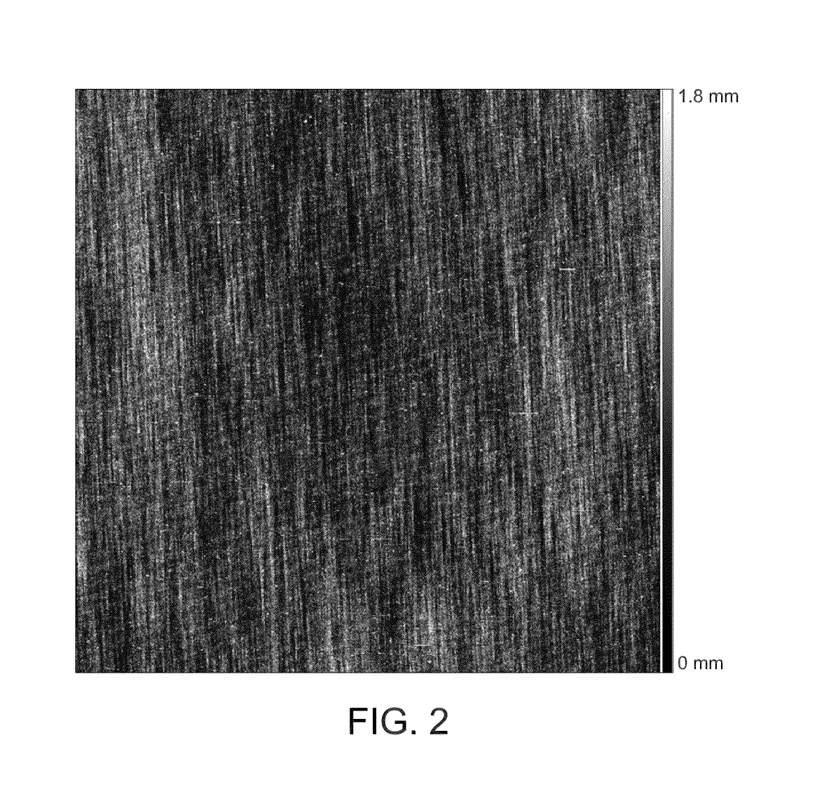

FIG. 2 shows a 15 μm epitaxial layer grown at 30 μm/hr at a lower reactor pressure of 100 mbar. This causes a further reduction in the surface roughness to 0.23 nm. The lower pressure regime is found to be further beneficial to surface roughness after the optimized etch and buffer.

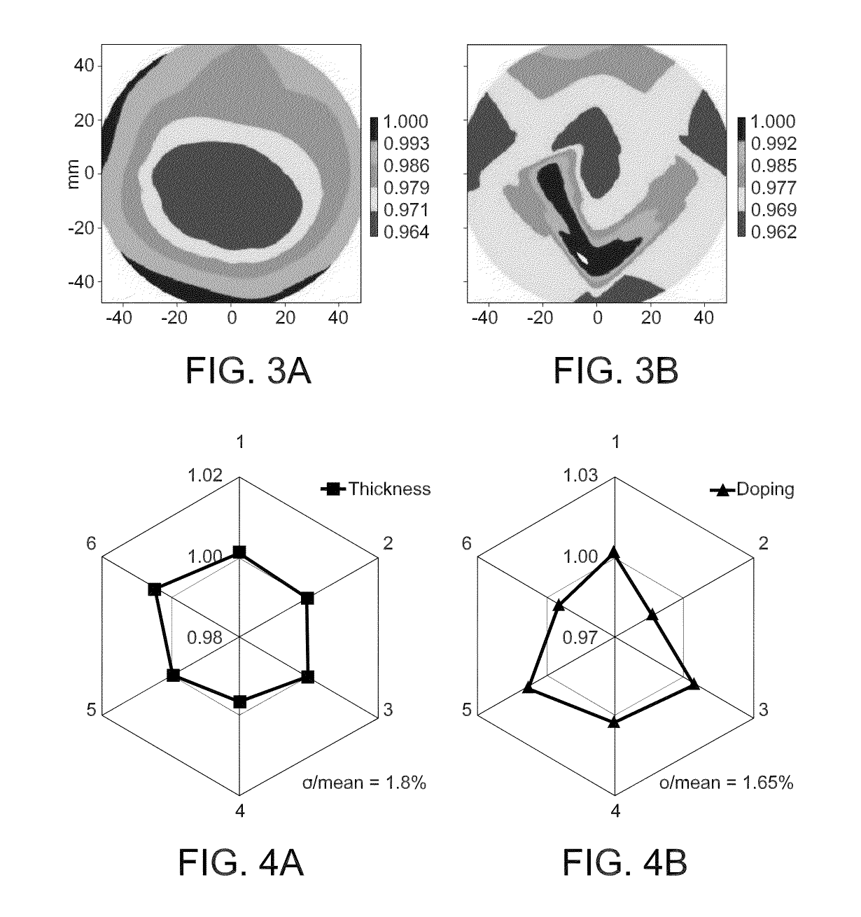

Another focus of this work was to develop epitaxial growth processes with very good thickness and doping uniformities. The uniformities were optimized with a combination of H₂ flows, Cl/Si ratio and satellite rotation. To maintain similar uniformities at higher growth rates of 30 μm/hr, the Cl/Si ratio had to be increased from 1.0 to 3.0. The typical thickness uniformities obtained on 15 μm epitaxial layers were 1.75% (s/mean), and 2.54% (max-min/max+min). The typical doping uniformities on the same epitaxial layers were 1.46% (s/mean), and 1.96% (maxmin/max+min). FIG. 3 shows the normalized intra-wafer thickness and doping profiles.

FIG. 4 shows the normalized wafer to wafer thickness and doping variation on a fully loaded six wafer run. Under typical process conditions, average intra-wafer thickness and doping uniformities of 1.8% and 1.65% were achieved. Good wafer-to-wafer thickness and doping homogeneity of 0.9% and 2.0% respectively was observed.

Run-to-run repeatability of the process was observed for two different product lines (Diodes and FETs) with different epi stacks and specifications. Data collected over 30 product runs (180 wafers) show very consistent repeatability for both thickness and doping for both diodes and FETs. The variation for FETs was found to be 0.7% and 2.78% for thickness and doping respectively. For diodes, the variations were 1% and 3.79% for thickness and doping respectively.

### Epitaxial Quality

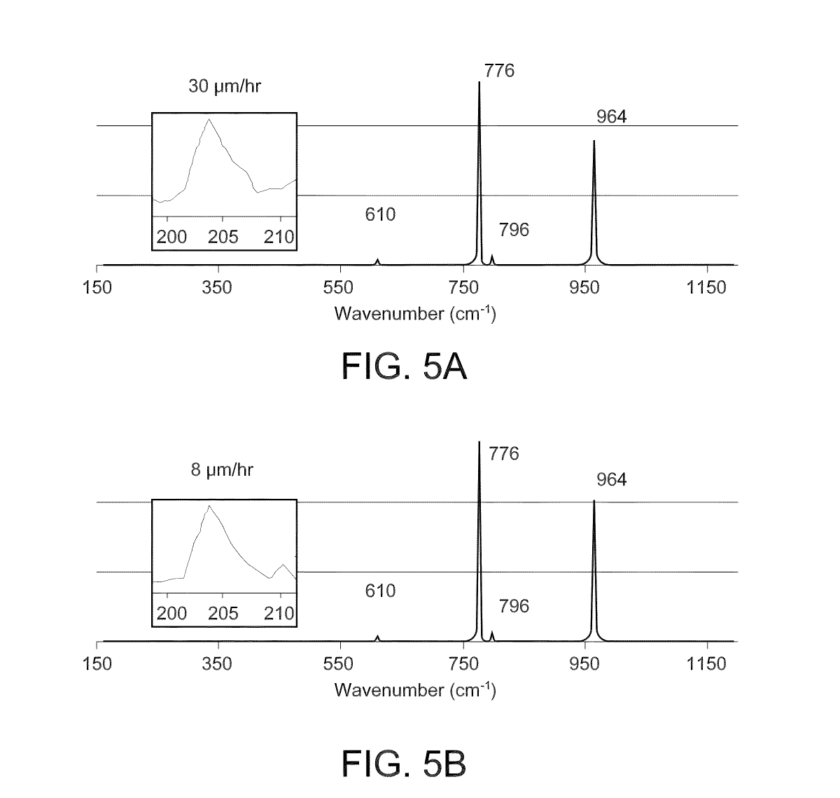

Epitaxial layer quality was evaluated using Raman spectra and x-ray diffraction (XRD). FIG. 5 shows the Raman spectra of 15 μm epitaxial layers grown with the two optimized growth processes of 8 μm/hr and 30 μm/hr. The typical peaks of the 4H—SiC polytype are seen at 204 cm⁻¹ (inset), 610 cm⁻¹, 776 cm⁻¹, 796 cm⁻¹ and 964 cm⁻¹ [6, 7]. No difference was seen between the epilayers grown with the different optimized growth rate processes.

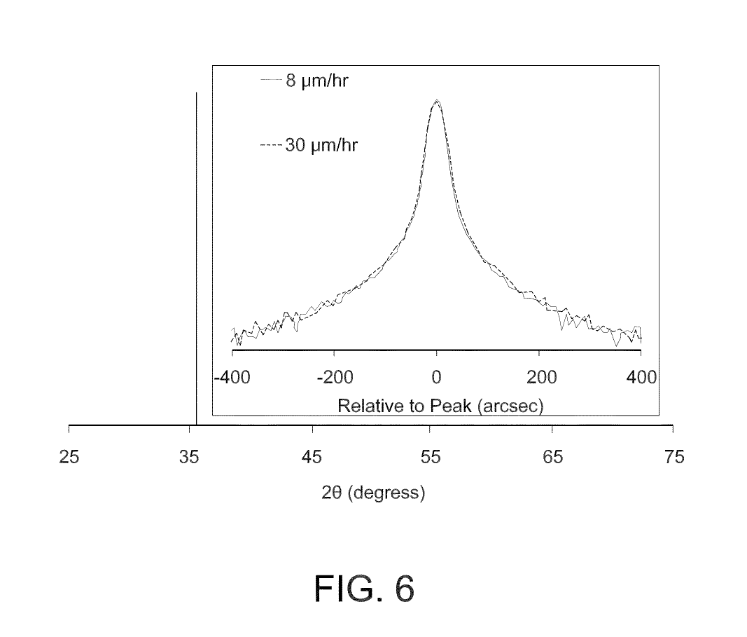

FIG. 6 shows the XRD data with the inset showing the rocking curves of the 8 μm/hr and 30 μm/hr growth rate processes. The strong peak corresponding to the (0004) planes of 4H—SiC was seen at 35.57°. The full width at half maximum (FWHM) of the rocking curves for the 8 μm/hr and 30 μm/hr growth rate epi were 23.0 and 26.6 arcseconds respectively. Both the Raman and the XRD data show the epitaxial layers grown by both the processes are of high crystal quality.

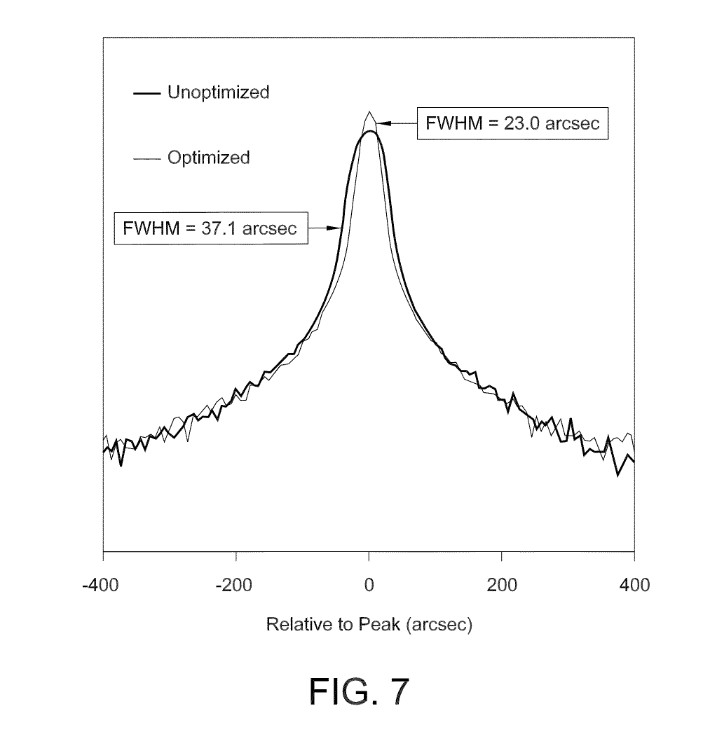

FIG. 7 shows the XRD rocking curves of two epitaxial layers grown with and without the optimizations. The un-optimized epitaxial layer has a wider peak having a FWHM of 37.1 arcsec. The optimized epitaxial layer is of better quality exhibiting a narrower peak having a FWHM of 23.0 arcsec.

While the foregoing specification teaches the principles of the present invention, with examples provided for the purpose of illustration, it will be appreciated by one skilled in the art from reading this disclosure that various changes in form and detail can be made without departing from the true scope of the invention.

### REFERENCES

[1] K. Wada, T. Kimoto, K. Nishikawa, H. Matsunami, Journal of Crystal Growth 291 (2006) 370.
[2] S. Leone, H. Pedersen, A. Henry, O. Kordina, E. Janze'n, Journal of Crystal Growth 311 (2009), pp. 3265-3272.
[3] Bernd Thomas, Christian Hecht, and Birgit Kallinger, Materials Science Forum Vols. 615-617 (2009), pp. 77.
[4] T. Aigo, A. Tsuge, H. Yashiro, T. Fujimoto, M. Katsuno, M. Nakabayashi, T. Hoshino, and W. Ohashi, Materials Science Forum, Vols. 645-648 (2010), pp. 119-122.
[5] Swapna Sunkari, Hrishikesh Das, Carl Hoff, Yaroslav Koshka, Janna Casady, Jeff Casady, Materials Science Forum Vols. 615-617 (2009), pp. 423.
[6] Nakashima S, Harima H., Phys Status Solidi A, 162 (1997) pp. 39.
[7] Wu Hailei, Sun Guosheng, Yang Ting, Yan Guoguo, Wang Lei, Zhao Wanshun, Liu Xingfang, Zeng Yiping, and Wen Jialiang, Journal of Semiconductors, Vol. 32, (2011), 043005-1.

1. A method comprising:
heating a semiconductor substrate to a first temperature of 1300-1500° C.;
contacting a surface of the substrate with hydrogen and HCl;
subsequently increasing the temperature of the substrate to a second temperature of at least 1550° C.;
epitaxially growing SiC on the surface of the substrate to form a SiC epitaxial layer on the substrate.

2. The method of claim 1, wherein the substrate is a 4H—SiC substrate.

3. The method of claim 2, wherein the surface of the substrate is inclined relative to the (0001) basal plane of the substrate.

4. The method of claim 3, wherein the surface of the substrate is inclined at an angle of <6° relative to the (0001) basal plane of the substrate.

5. The method of claim 3, wherein the surface of the substrate is inclined at an angle of <4° relative to the (0001) basal plane of the substrate.

6. The method of claim 1, wherein the second temperature is 1550° C.-1650° C.

7. The method of claim 1, wherein the second temperature is 1650° C.-1700° C.

8. The method of claim 1, wherein epitaxially growing comprises contacting the surface of the substrate with a C containing gas and a Si containing gas.

9. The method of claim 8, wherein epitaxially growing comprises contacting the surface of the substrate with a C containing gas and a Si containing gas at a C/Si ratio of 0.5-0.8.

10. The method of claim 8, wherein epitaxially growing comprises:
contacting the surface of the substrate with a C containing gas and a Si containing gas at a C/Si ratio of 0.5-0.8 to form a SiC buffer layer on the surface of the substrate; and
subsequently contacting the surface with a C containing gas and a Si containing gas at a C/Si ratio >0.8 to form the SiC epitaxial layer on the SiC buffer layer.

11. The method of claim 10, wherein the SiC buffer layer is grown at a lower growth rate than the SiC epitaxial layer.

12. The method of claim 10, wherein the SiC buffer layer is grown at a growth rate of 1 μm/hr to 8 μm/hr and/or wherein the SiC epitaxial layer is grown at a growth rate of at least 10 μm/hr.

13. The method of claim 8, wherein the carbon containing gas is C₃H₈ and/or wherein the Si containing gas is SiH₄.

14. The method of claim 1, wherein epitaxially growing SiC on the surface of the substrate comprises epitaxially growing the SiC at a growth rate of at least 10 μm/hr.

15. The method of claim 1, wherein epitaxially growing SiC on the surface of the substrate comprises epitaxially growing the SiC at a pressure of 100 mbar to 200 mbar.

16. A method comprising:
heating a substrate to a temperature of at least 1550° C.;
contacting a surface of the substrate with a C containing gas and a Si containing gas at a C/Si ratio of 0.5-0.8 to form a SiC buffer layer on the surface of the substrate; and
subsequently contacting the surface of the SiC buffer layer with a C containing gas and a Si containing gas at a C/Si ratio >0.8 to form a SiC epitaxial layer on the SiC buffer layer.

17. The method of claim 16, wherein the SiC buffer layer is grown at a lower growth rate than the SiC epitaxial layer.

18. The method of claim 16, wherein the SiC buffer layer is grown at a growth rate of 1 μm/hr to 8 μm/hr and/or wherein the SiC epitaxial layer is grown at a growth rate of at least 10 μm/hr.

19. The method of claim 16, wherein the second temperature is 1550° C.-1650° C.

20. The method of claim 16, wherein the second temperature is 1650° C.-1700° C.

21. The method of claim 16, wherein the substrate is a 4H—SiC substrate.

22. An article of manufacture made by the method of claim 1, wherein the SiC epitaxial layer has an RMS surface roughness of <1 nm or <0.4 nm or <0.35 nm.

23. An article of manufacture made by the method of claim 16, wherein the SiC epitaxial layer has an RMS surface roughness of <1 nm or <0.4 nm or <0.35 nm.

24. (canceled)

25. The article of manufacture of claim 22, wherein the SiC epitaxial layer has a thickness of at least 10 μm or at least 50 μm.

26. The article of manufacture of claim 23, wherein the SiC epitaxial layer has a thickness of at least 10 μm or at least 50 μm.

27. The article of manufacture of claim 22, wherein the SiC epitaxial layer does not exhibit step bunching.

28. The method of claim 1, wherein epitaxially growing SiC on the surface of the substrate comprises epitaxially growing the SiC at a pressure of 80 mbar to 120 mbar, 90 mbar to 110 mbar or 95 mbar to 105 mbar.

29. The method of claim 16, wherein the SiC epitaxial layer is formed at a pressure of 80 mbar to 120 mbar, 90 mbar to 110 mbar or 95 mbar to 105 mbar.
